(19) United States
(12) Patent Application Publication
(10) Pub. No.: US 2012/0326211 A1
(43) Pub. Date: Dec. 27, 2012

(54) BIPOLAR HIGH ELECTRON MOBILITY TRANSISTOR AND METHODS OF FORMING SAME

(76) Inventors: Kevin S. Stevens, Providence, RI (US); Charles R. Lutz, Seekonk, MA (US)

(21) Appl. No.: 13/528,937

(22) Filed: Jun. 21, 2012

Related U.S. Application Data
(60) Provisional application No. 61/500,546, filed on Jun. 23, 2011.

(51) Int. Cl. H01L 27/06; H01L 21/8248

(52) U.S. Cl. 257/195; 438/312; 257/E27.015; 257/E21.695

(57) ABSTRACT

An epilayer structure includes a field-effect transistor structure and a heterojunction bipolar transistor structure. The heterojunction bipolar transistor structure contains an n-doped subcollector and a collector formed in combination with the field-effect transistor structure, wherein at least a portion of the subcollector or collector contains Sn, Te, or Se. In one embodiment, a base is formed over the collector; and an emitter is formed over the base. The bipolar transistor and the field-effect transistor each independently contain a III-V semiconductor material.

### RELATED APPLICATION

This application claims the benefit of U.S. Provisional Application No. 61/500,546, filed on Jun. 23, 2011.

The entire teachings of the above application are incorporated herein by reference.

### BACKGROUND OF THE INVENTION

Gallium arsenide (GaAs) heterojunction bipolar transistor (HBT) integrated circuits have developed into an important technology for a variety of applications, particularly as power amplifiers (PAs) for wireless communications systems. Future needs are expected to require devices with increased levels of integration to improve performance or functionality, reduce footprint size, or decrease cost. One method to achieve such integration is to combine an HBT PA with a Radio frequency (RF) switch formed from a GaAs pseudomorphic high electron mobility transistor (pHEMT).

In order to monolithically integrate the HBT and pHEMT devices, bipolar high electron mobility transistor (BiHEMT) structures have been used. A typical BiHEMT epitaxial structure consists of HBT epitaxial layers grown on top of HEMT epitaxial layers. The combined epilayer structure of a BiHEMT is extremely challenging to produce and can include more than thirty discrete layers. Such epilayer structures can be formed, for example, by growth techniques such as metalorganic chemical vapor deposition (MOCVD) or molecular beam epitaxy (MBE). Alternatively the sequence of these layers may be reversed and it may be advantageous to grow the HEMT on top of the HBT. Such devices are also sometimes known as a Bipolar-Field Effect Transistors (BiFET).

To fabricate the pHEMT devices in the BiHEMT structure, it is necessary to etch or remove the HBT layers above the pHEMT layers. This leads to significant device processing challenges due to a large height difference (typically 1-3 μm) between the pHEMT surface and the HBT surface. Any reduction in this height differential would help alleviate these processing challenges. The subcollector and collector layers of the HBT are obvious choices on which to focus these efforts as they make up a large percentage of the height differential. The subcollector layer is typically located below the collector layer and is typically grown with higher doping density. It should be noted, however, that the term “collector” is used herein to refer to the entirety of collector and subcollector layers found below the base of the HBT, whereas the term “subcollector” refers to the highly doped layer below the collector as shown in FIG. 1.

Although it is desirable to thin the collector layer, this tends to reduce transistor breakdown voltages and degrades device robustness. Thinning the subcollector layer increases the collector sheet resistance and transistor parasitic resistance. By increasing the doping in the subcollector, collector sheet resistance can be reduced. However, most state-of-the-art subcollector epilayers of n-p-n GaAs-based HBTs are already doped with Si near the upper limit, commonly referred to as “saturation.” Furthermore, the growth of additional layers (e.g., the base and emitter structures of the HBT) above the collector and subcollector can degrade the GaAs:Si sheet resistance and electron concentration due to the annealing effect during the growth of the additional layers. This annealing can cause a significant reduction in electron concentration of conventional Si-doped GaAs films relative to their as-grown values. These results can be explained via the interaction of three phenomena: a) an increasing equilibrium concentration of gallium vacancies; b) the tendency of gallium vacancies to form complexes with silicon donor atoms thereby rendering the dopant atom inactive; and c) the influence that growth conditions have on the non-equilibrium state under which GaAs is grown. [1].

Therefore, a need exists for a BiHEMT that overcomes or minimizes the above-referenced problems.

### SUMMARY OF THE INVENTION

The present invention provides a BiHEMT epilayer structure, comprising a field-effect transistor structure including a contact layer, and a heterojunction bipolar transistor structure formed over the field-effect transistor structure. The heterojunction bipolar transistor structure contains an n-doped subcollector and collector formed over the contact layer of the field-effect transistor structure, wherein at least one of the subcollector and the collector each independently includes at least one member of the group consisting of Sn, Te, and Se. A base is over the collector, and an emitter is over the base, wherein at least one of the collector and subcollector of the heterojunction bipolar transistor and field-effect transistor structures, and the contact layer of the field-effect transistor structure, each independently contain a III-V semiconductor. Examples of suitable materials of the collector and the subcollector include GaAs, AlGaAs and InGaP. Preferably the subcollector and collector include GaAs. Also, preferably, the collector and subcollector are formed of the same material, although they can be formed of different materials. In a preferred embodiment, the III-V semiconductor material includes gallium and arsenic. The thickness of the collector typically is between about 5,000 Å and 3 μm. The thickness of the subcollector typically is between about 3,000 Å and 2 μm. In another preferred embodiment, the field-effect transistor is a high electron mobility transistor.

Typically, the concentration of Sn, Te or Se dopant in the collector is between about 1E15 cm-3 (1×10¹⁵ parts per cubic centimeter) and about 5E17 cm-3. In another embodiment, the collector can be doped with silicon. In one embodiment, at least a portion of the subcollector is n-type with a Sn, Te or Se concentration of greater than 1E18 cm-3, whereas in another embodiment, at least a portion of the subcollector is n-type with electron concentration greater than 1E19 cm-3.

In a preferred embodiment, the emitter is selected from the materials InGaP, AlInGaP, or AlGaAs. In still another preferred embodiment, the base is doped with carbon at a concentration of about 1E19 cm-3 to about 7E19 cm-3.

The present invention also provides methods for forming a bipolar high electron mobility transistor whereby a heterojunction bipolar transistor is formed over a field effect transistor; wherein the collector layer is doped with Sn, Te, or Se. In a preferred embodiment, these layers are formed by metalorganic chemical vapor deposition.

The present invention provides structures and methods to increase the maximum doping and decrease the minimum sheet resistance limits of the collector and/or subcollector of the BiHEMT structures. By doping the collector and subcollector layers with Sn, Te, or Se, including combinations of these, the negative impact due to sheet resistance and electron concentration degradation of GaAs:Si layers can be mitigated. The resultant BiHEMT devices can exhibit reduced subcollector thickness, enabling reduced topology and improved device processing, while preserving the desired low collector sheet resistance.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 is a schematic of a BiHEMT epilayer structure illustrating the monolithic incorporation of both pHEMT and BiHEMT layers on the same wafer and the topology between the surfaces of the HBT and pHEMT devices formed from these epilayers.

FIGS. 2A and 2B are plots of prior art sheet resistance (FIG. 2A) and electron concentration (FIG. 2B) of GaAs:Si layers illustrating an increase in sheet resistance and decrease in electron concentration upon annealing. The x-axis is total dopant flow, a measure of how much Si is introduced into the reactor during epilayers growth.

FIGS. 3A and 3B are plots of sheet resistance (FIG. 3A) and electron concentration (FIG. 3B) of GaAs:Sn layers of the invention, illustrating a reduced impact of annealing on sheet resistance and electron concentration relative to GaAs:Si (FIG. 2). The x-axis is total dopant flow, a measure of how much Sn is introduced into the reactor during epilayer growth.

FIGS. 4A and 4B are plots of sheet resistance (FIG. 4A) and electron concentration (FIG. 4B) of GaAs:Te layers of the invention, illustrating reduced impact of annealing on sheet resistance and electron concentration relative to both GaAs:Si (FIG. 2) and GaAs:Sn (FIG. 3). The x-axis is total dopant flow, a measure of how much Te is introduced into the reactor during epilayer growth.

### DETAILED DESCRIPTION OF THE INVENTION

A description of example embodiments of the invention follows.

While this invention has been particularly shown and described with references to example embodiments thereof, it will be understood by those skilled in the art that various changes in form and details may be made therein without departing from the scope of the invention encompassed by the appended claims.

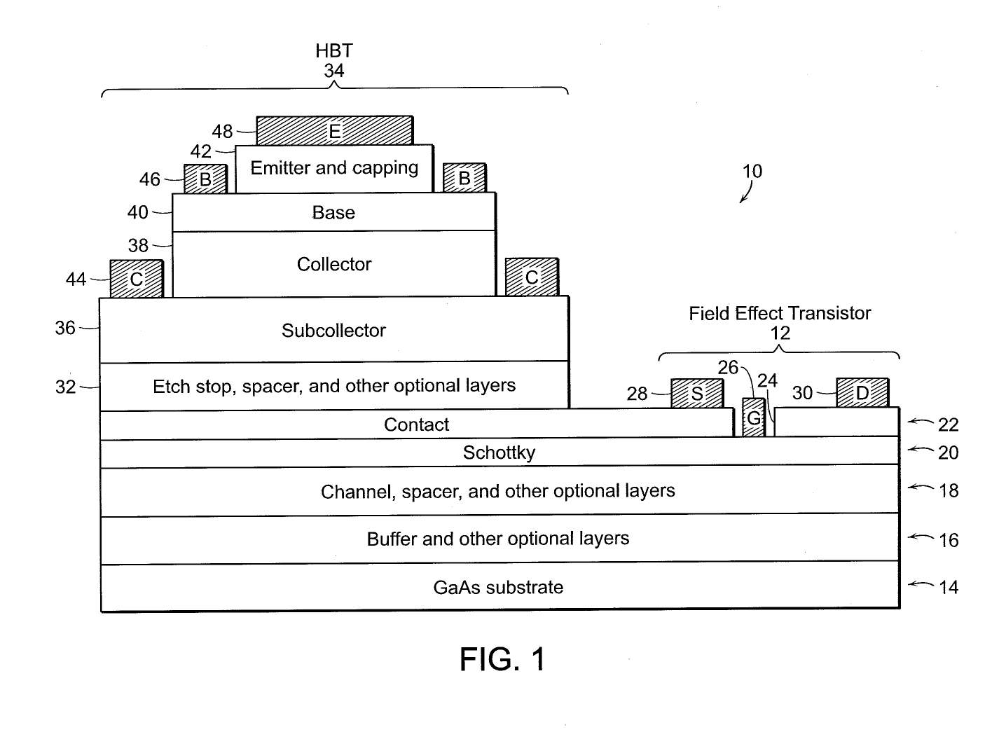

FIG. 1 is a schematic of a representative BiHEMT epilayer structure of the invention. Note that the layers of the HBT are removed during device fabrication to form the pHEMT on underlying layers. This results in significant topology between the surface of the HBT and the pHEMT. Such topology can cause problems during lithographic steps, particularly those for the pHEMT. For pHEMT switches, the smallest feature is typically the gate electrode and precise optics are required to define dimensions of <1 μm. The topology of the BiHEMT wafer can cause nonuniform photoresist thickness and/or depth-of-focus problems for optical systems used to print the gate pattern. To mitigate some of these issues, it may be necessary to laterally separate the pHEMT from the BiHEMT, but this can waste chip area. It should be noted that the layers shown in FIG. 1 are representative and have been simplified for illustration. Additional layers, graded layers, and other material designs are expected to be present in typical BiHEMTs.

As shown in FIG. 1 BiHEMT epilayer structure 10 is grown on a substrate 14. In one embodiment, substrate 14 consists essentially of gallium arsenide (GaAs). Buffer layer 16 is over substrate 14. In one embodiment, buffer layer 16 includes GaAs and AlGaAs. Typically, the thickness of buffer layer 16 is in a range of between about 500 Å and about 5000 Å. Optionally, other layers can be employed instead of buffer layer 16, or in addition to buffer layer 16, and in any combination with buffer layer 16. Examples of other optional layers include layers of superlattice structures comprised of alternating layers of low/high energy gap materials such as GaAs and AlGaAs or GaAs and InGaAs with thicknesses between about 10 Å to about 300 Å. Channel layer 18 is grown over buffer layer 16 or its alternative or additional layers. Examples of suitable materials of channel layer 18 include GaAs and InGaAs with layer thickness ranging from about 20 Å to 200 Å. Optionally, a spacer layer or other optional layers (not shown) can be over (or under) channel layer 18. Suitable materials for use in forming a spacer layer include GaAs, AlGaAs, InGaP, and AlInGaP with thickness from 20 Å to 100 Å. Examples of other optional layers can include, for example, GaAs, AlGaAs, InGaP, AlInGaP, InGaAs with thicknesses between about 5 Å and 50 Å. Schottky layer 20 is over channel layer 18. Examples of suitable materials Schottky layer 20 include AlGaAs, InGaP, and AlInGaP with thickness ranging from about 100 Å to 1500 Å. Contact layer 22 is over Schottky layer 20. Examples of suitable materials of contact layer 22 include GaAs, AlGaAs, and InGaP with thickness between about 100 Å to 2000 Å. Contact layer 22 includes recessed portion 24. All of layers 16, 18, 20 and 22 can be fabricated by a suitable method known in the art, such as metal organic chemical vapor deposition or molecular beam epitaxy. Recess 24 can be formed by a suitable technique known in the art, such as lithography and etching. Gate contact 26 is located within recessed portion 24. Source contact 28 and drain contact 30 are located at contact layer 22, or are in electrical communication with contact layer 22.

BiHEMT epilayer structure also, optionally, includes etch stop, spacer, or other optional layers 32 at contact layer 22. Examples of suitable etch stop layers include AlGaAs, AlAs, or InGaP ranging in thickness from about 10 Å to 500 Å.

BiHEMT epilayer structure 10 also includes heterojunction bipolar transistor (HBT) component 34. HBT 34 includes sub-collector 36. Examples of suitable materials of sub-collector 36 include a III-V semiconductor material. In one embodiment, the III-V semiconductor material includes gallium and arsenic. Examples of specific materials of subcollector 36 include gallium arsenide (GaAs), aluminum gallium arsenide (AlGaAs), indium gallium phosphide (InGaP) and InP and InGaAs for InP based HBTs. Subcollector 36 is doped with at least one element selected from the group consisting of tin (Sn), telluriam (Te) and selenium (Se). In one embodiment, the concentration of doping of the subcollector 36 is in a range of between about 1×10¹⁸ cm⁻³ and about 1×10²⁰ cm⁻³. Alternatively, the concentration of doping is in a range between about 1×10¹⁹cm⁻³ and about 6×10¹⁹cm⁻³. In one embodiment, the thickness of subcollector layer 36 is in the range of between about 2000 Å and about 4 μm. In another embodiment, the thickness of subcollector 36 is in a range of between about 3000 Å and about 2 μm.

Collector 38 is over subcollector 36. In one embodiment, collector 38 includes a III-V semiconductor material that includes gallium and arsenic. The material of collector 38 can be the same material or a different III-V semiconductor material as that of subcollector 36. Either or both of subcollector 36 and collector 38 can be doped with silicon. In one embodiment, collector 38 is doped only with silicon. In another embodiment, collector 38 is doped with at least one tin (Sn), tellurium (Te) and selenium (Se) in addition to, or in the absence of silicon (Si). In one embodiment, the concentration of at least one of tin, tellurium or selenium dopant is, collectively, in a range of between about 1×10¹⁵ cm⁻³ and about 5×10¹⁷ cm⁻³. The doping in the collector can be graded with various profiles according to intended application and desired electrical performance of the device.

Base 40 is over collector 38. In one embodiment, base 40 consists essentially of at least one member selected from the group consisting of GaAs, GaAsSb, GaInAs, GaInAsN. In one embodiment, base 40 is doped with carbon. In a specific embodiment, base 40 is doped with carbon at a concentration of between about 1×10^{19 cm}⁻³ and about 7×10¹⁹ cm⁻³.

Emitter 42 is over base 40 and, optionally, emitter 42 includes a capping layer. Suitable capping layer materials can include GaAs, AlGaAs, InGaP, AlInGaP, InP and AlInP. Typical dopants can include Si, Sn, Se, and Te. Dopant concentrations for the emitter layer range from about 5×10¹⁶ cm⁻³ to 1×10¹⁸ cm⁻³. The emitter capping layers are typically doped between 1×10¹⁸ cm⁻³ to 3×10¹⁹ cm⁻³.

BiHEMT 10 includes electrical contacts gate 36, source 28 and drain 30 at pHEMT 12, and contacts 44, 46 and 48 at HBT 34. Examples of suitable materials of these electrical contacts are titanium, platinum and gold. Etch stop 32, subcollector 36, collector 38, base 40 and emitter 42 layers can be formed by the same method as the layers of pHEMT 12 are formed, including, for example, techniques known to those skilled in the art, such as metal organic chemical vapor deposition and molecular beam epitaxy.

In the context of the present invention, the term BiHEMT is used to describe any epilayer structure that incorporates the functionality of a bipolar transistor and field-effect transistor, regardless of the sequence of the structures or the nomenclature. For example, as an alternative to the BiHEMT 10, shown in FIG. 1, pHEMT 34 is formed over HBT 12, another embodiment of the invention.

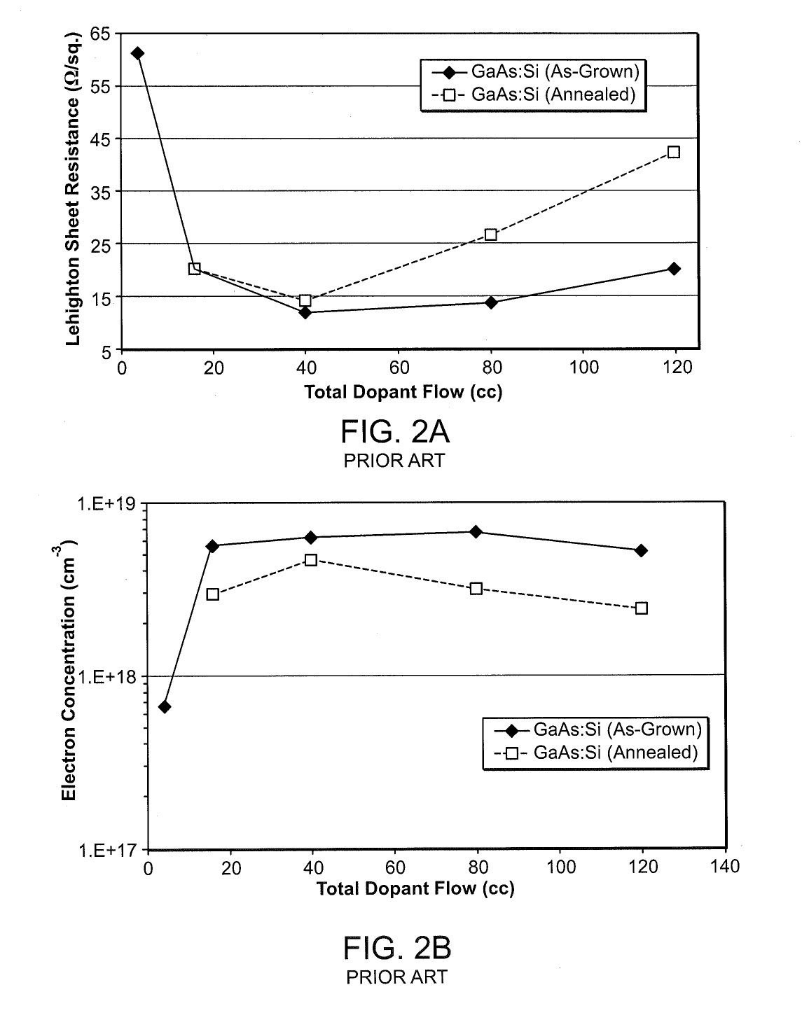

Reference data in FIG. 2A shows the sheet resistance (Rs) of 0.5 μm n+GaAs:Si layers versus total dopant (disilane) flow. As-grown (i.e., in layers where growth was terminated immediately following the GaAs:Si film), maximum active doping levels are in the mid-E18 cm-3 range. The impact of annealing the subcollector layer (as a means to mimic subsequent overgrowth of HBT layers during growth of BiHEMT structures) is shown in FIG. 2B. The Rs and electron concentration obtained from GaAs:Si films is significantly different between annealed and unannealed samples. These data indicate that the active doping (number of dopant atoms contributing to n-type conductivity) decreases significantly after annealing and that this is the dominant factor limiting minimum attainable sheet resistances in n+GaAs:Si HBT subcollector layers in a BiHEMT device.

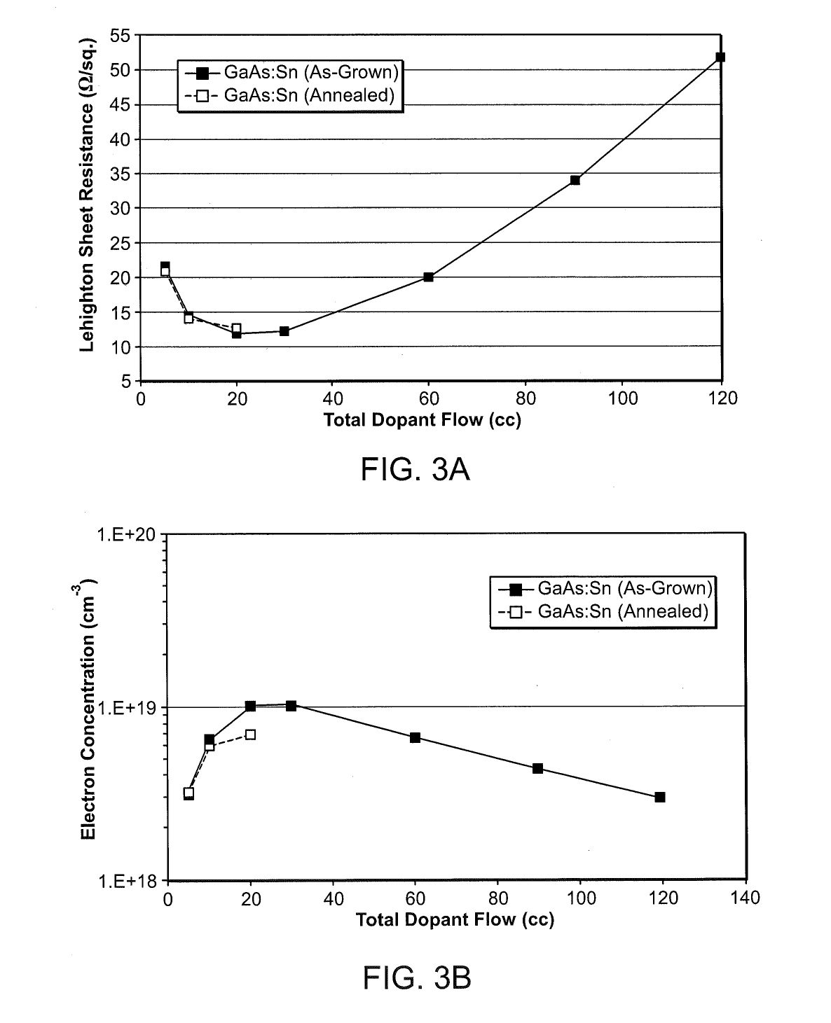

FIG. 3A shows the sheet resistance Rs of 0.5 μm n+GaAs:Sn layers versus total dopant flow. As-grown, maximum active doping level shown in FIG. 3B is about 1E19 cm-3, higher than for GaAs:Si shown in FIG. 2. The impact of annealing the subcollector layer is still evident, as shown in FIG. 3B, but the increase in Rs with annealing is less substantial than for Si-doped films. The peak electron concentration achieved with GaAs:Sn is about 7E18 cm-3, or about 40% higher than for GaAs:Si shown in FIG. 2B.

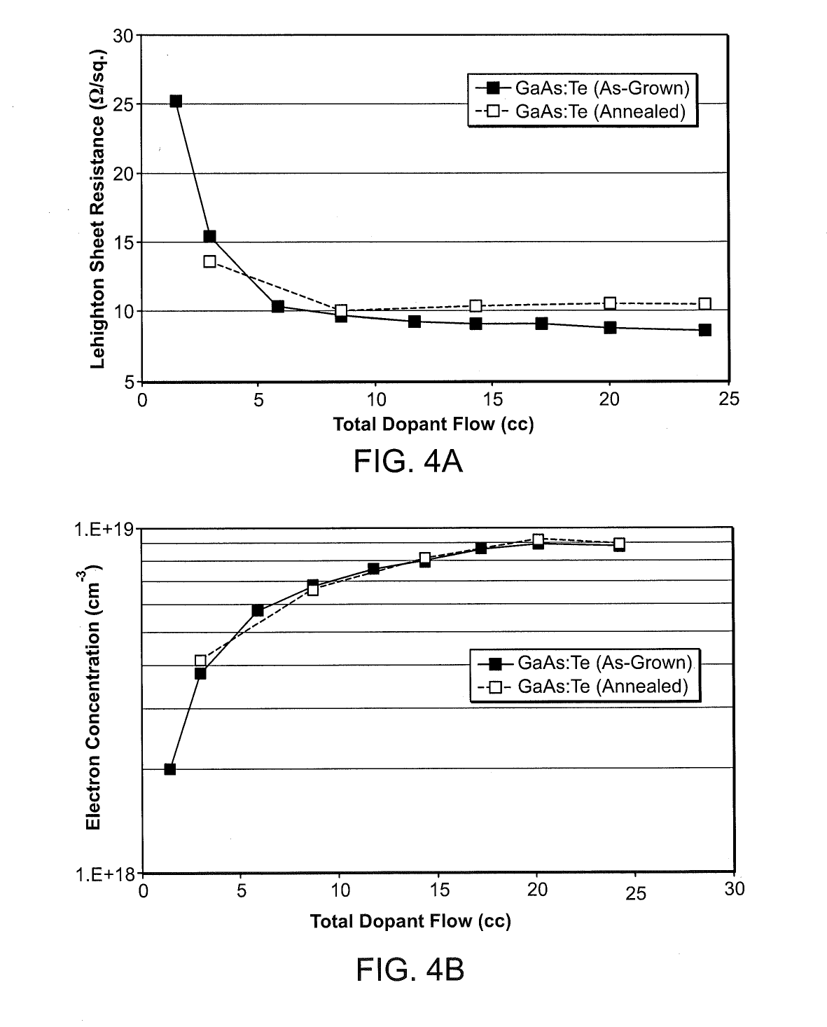

FIG. 4A shows the Rs of 0.5 μm n+GaAs:Te layers versus total dopant flow. As-grown, maximum active doping level is about 9E18 cm-3, slightly less than for GaAs:Sn shown in FIG. 3A. However, the impact of annealing the subcollector layer, as shown in FIG. 4B, is significantly reduced and is essentially absent. This results in an additional increase in electron concentration above both GaAs:Si shown in FIG. 2B and GaAs:Sn shown in FIG. 3B, to a value of about 9E18 cm-3. The sheet resistance of the annealed GaAs:Te is about 10 ohms/sq., lower than can be achieved by conventional Si doping or by Sn doping.

The relevant portions of all references cited herein are incorporated herein by reference in their entirety.

### REFERENCES

[1] H. Fushimi, M. Shinohara, and K. Wada, J. Appl. Phys., 81, 1745 (1997).

What is claimed is:

1. An epilayer structure, comprising:
(a) a field-effect transistor structure that includes a contact layer; and
(b) a heterojunction bipolar transistor structure formed over the field-effect transistor structure, wherein the heterojunction bipolar transistor structure contains
i) an n-doped subcollector over the contact layer of the field-effect transistor structure,
ii) a collector over the subcollector, wherein at least one of the subcollector and the collector each independently include at least one member of the group consisting of Sn, Te and Se,
iii) a base over the collector, and
iv) an emitter over the base,
wherein at least one of the collector and the subcollector of the heterojunction bipolar transistor structure, and the contact layer of the field-effect transistor structure, each independently contain a III-V semiconductor material.

2. The epilayer structure of claim 1, wherein the III-V semiconductor material includes gallium and arsenic.

3. The epilayer structure of claim 1, wherein the field-effect transistor is a high electron mobility transistor.

4. The epilayer structure of claim 1, wherein at least a portion of the subcollector is an n-type material with an electron concentration greater than about 1E18 cm-3.

5. The epilayer structure of claim 1, wherein at least a portion of the subcollector is an n-type material with an electron concentration greater than about 1E19 cm-3.

6. The epilayer structure of claim 1, wherein the emitter consists essentially of at least one member of the group consisting of InGaP, AlInGaP and AlGaAs.

7. The epilayer structure of claim 1, wherein the base is doped with carbon at a concentration of between about 1E19 cm-3 and about 7E19 cm-3.

8. A method of forming a bipolar high electron mobility transistor structure, comprising the steps of:
a) forming a subcollector over a contact layer of a high electron mobility transistor structure; and
b) forming a collector over the subcollector, wherein at least one of the subcollector and the collector each independently include at least one member of the group consisting of Sn, Te and Se.

9. The method of claim 8, wherein the at least one of the subcollector and collector layers are formed by metal-organic chemical vapor deposition.
